(19) United States
(12) Patent Application Publication
(10) Pub. No.: US 2025/0374634 A1
(43) Pub. Date: Dec. 4, 2025

(54) SEMICONDUCTOR DEVICE STRUCTURE AND METHODS OF FORMING THE SAME

(71) Applicant: TAIWAN SEMICONDUCTOR MANUFACTURING COMPANY, LTD., Hsinchu (TW)

(72) Inventors: Mu-Chieh CHANG, Hsinchu (TW); Wen-Kai LIN, Hsinchu (TW); Yi-Yun TSAI, Hsinchu (TW); Che-Hao CHANG, Hsinchu (TW); Tai-Chun HUANG, Hsinchu (TW); Wei-Yang LEE, Taipei (TW); Chi On CHUI, Hsinchu (TW)

(21) Appl. No.: 18/830,670

(22) Filed: Sep. 11, 2024

Related U.S. Application Data
(60) Provisional application No. 63/654,182, filed on May 31, 2024.

(51) Int. Cl. H01L 29/66; H01L 29/06; H01L 29/423; H01L 29/775; H01L 29/786

(52) U.S. Cl. CPC H10D 64/021; H10D 64/015; H10D 30/43; H10D 30/6735; H10D 30/6757; H10D 62/121

(57) ABSTRACT

Embodiments of the present disclosure provide a semiconductor device structure and methods of forming the same. The structure includes a substrate portion extending from a substrate, a semiconductor layer disposed over the substrate portion, a gate structure surrounding at least a portion of the semiconductor layer, and first and second dielectric spacers disposed on the semiconductor layer. A portion of the gate structure is disposed between the first and second dielectric spacers, and each of the first and second dielectric spacer includes a first spacer layer and a second spacer layer disposed adjacent the first spacer layer. The second spacer layer has an outer edge and an inner edge, and a length of the outer edge is substantially greater than a length of the inner edge.

### CROSS-REFERENCE TO RELATED APPLICATIONS

This application claims priority to U.S. Provisional Application Ser. No. 63/654,182 filed May 31, 2024, which is incorporated by reference in its entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

Therefore, there is a need to improve processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-6 are perspective views of various stages of manufacturing a semiconductor device structure, in accordance with some embodiments.

FIGS. 7A-8A are cross-sectional side views of various stages of manufacturing the semiconductor device structure taken along line A-A of FIG. 6, in accordance with some embodiments.

FIGS. 7B-8B are cross-sectional side views of various stages of manufacturing the semiconductor device structure taken along line B-B of FIG. 6, in accordance with some embodiments.

FIGS. 7C-8C are cross-sectional side views of various stages of manufacturing the semiconductor device structure taken along line C-C of FIG. 6, in accordance with some embodiments.

FIGS. 9A-9D are cross-sectional side views of various stages of manufacturing the semiconductor device structure, in accordance with some embodiments.

FIGS. 10A-10D are cross-sectional side views of a dielectric spacer of the semiconductor device structure, in accordance with some embodiments.

FIGS. 11A and 11B are cross-sectional side views of various stages of manufacturing the semiconductor device structure, in accordance with alternative embodiments.

FIGS. 12A-12C are cross-sectional side views of various stages of manufacturing the semiconductor device structure, in accordance with alternative embodiments.

FIGS. 13A-16A are cross-sectional side views of various stages of manufacturing the semiconductor device structure taken along line A-A of FIG. 6, in accordance with some embodiments.

FIGS. 13B-16B are cross-sectional side views of various stages of manufacturing the semiconductor device structure taken along line B-B of FIG. 6, in accordance with some embodiments.

FIGS. 13C-16C are cross-sectional side views of various stages of manufacturing the semiconductor device structure taken along line C-C of FIG. 6, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

While the embodiments of this disclosure are discussed with respect to nanostructure channel FETs, such as gate all around (GAA) FETs, for example Horizontal Gate All Around (HGAA) FETs or Vertical Gate All Around (VGAA) FETs, implementations of some aspects of the present disclosure may be used in other processes and/or in other devices, such as planar FETs, Fin-FETs, and other suitable devices. A person having ordinary skill in the art will readily understand other modifications that may be made are contemplated within the scope of this disclosure. In cases where gate all around (GAA) transistor structures are adapted, the GAA transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

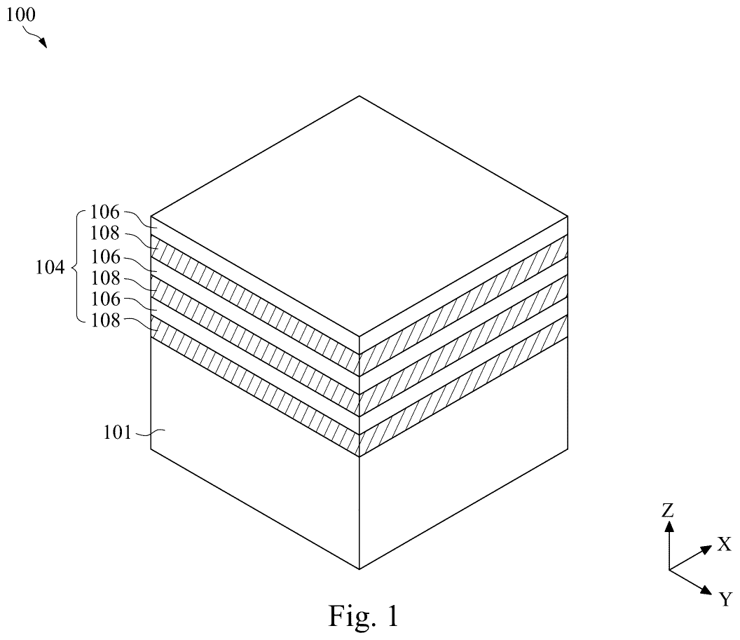

FIGS. 1-16C show exemplary processes for manufacturing a semiconductor device structure 100 according to embodiments of the present disclosure. It is understood that additional operations can be provided before, during, and after processes shown by FIGS. 1-16C, and some of the operations described below can be replaced or eliminated, for additional embodiments of the method. The order of the operations/processes is not limiting and may be interchangeable.

FIGS. 1-6 are perspective views of various stages of manufacturing a semiconductor device structure 100, in accordance with some embodiments. As shown in FIG. 1, a semiconductor device structure 100 includes a stack of semiconductor layers 104 formed over a front side of a substrate 101. The substrate 101 may be a semiconductor substrate. The substrate 101 may include a crystalline semiconductor material such as, but not limited to silicon (Si), germanium (Ge), silicon germanium (SiGe), gallium arsenide (GaAs), indium antimonide (InSb), gallium phosphide (GaP), gallium antimonide (GaSb), indium aluminum arsenide (InAlAs), indium gallium arsenide (InGaAs), gallium antimony phosphide (GaSbP), gallium arsenic antimonide (GaAsSb) and indium phosphide (InP). In some embodiments, the substrate 101 is a silicon-on-insulator (SOI) substrate having an insulating layer (not shown) disposed between two silicon layers for enhancement. In one aspect, the insulating layer is an oxygen-containing layer.

The substrate 101 may include various regions that have been doped with impurities (e.g., dopants having p-type or n-type conductivity). Depending on circuit design, the dopants may be, for example phosphorus for an n-type field effect transistors (NFET) and boron for a p-type field effect transistors (PFET).

The stack of semiconductor layers 104 includes alternating semiconductor layers made of different materials to facilitate formation of nanostructure channels in a multi-gate device, such as nanostructure channel FETs. In some embodiments, the stack of semiconductor layers 104 includes first semiconductor layers 106 and second semiconductor layers 108. In some embodiments, the stack of semiconductor layers 104 includes alternating first and second semiconductor layers 106, 108. The first semiconductor layers 106 and the second semiconductor layers 108 are made of semiconductor materials having different etch selectivity and/or oxidation rates. For example, the first semiconductor layers 106 may be made of Si and the second semiconductor layers 108 may be made of SiGe. In some examples, the first semiconductor layers 106 may be made of SiGe and the second semiconductor layers 108 may be made of Si. Alternatively, in some embodiments, either of the semiconductor layers 106, 108 may be or include other materials such as Ge, SiC, GeAs, GaP, InP, InAs, InSb, GaAsP, AlInAs, AlGaAs, InGaAs, GaInP, GaInAsP, or any combinations thereof.

The first and second semiconductor layers 106, 108 are formed by any suitable deposition process, such as epitaxy. By way of example, epitaxial growth of the layers of the stack of semiconductor layers 104 may be performed by a molecular beam epitaxy (MBE) process, a metalorganic chemical vapor deposition (MOCVD) process, and/or other suitable epitaxial growth processes.

The first semiconductor layers 106 or portions thereof may form nanostructure channel(s) of the semiconductor device structure 100 in later fabrication stages. The term nanostructure is used herein to designate any material portion with nanoscale, or even microscale dimensions, and having an elongated shape, regardless of the cross-sectional shape of this portion. Thus, this term designates both circular and substantially circular cross-section elongate material portions, and beam or bar-shaped material portions including, for example, a cylindrical in shape or substantially rectangular cross-section. The nanostructure channel(s) of the semiconductor device structure 100 may be surrounded by a gate electrode. The semiconductor device structure 100 may include a nanostructure transistor. The nanostructure transistors may be referred to as nanosheet transistors, nanowire transistors, gate-all-around (GAA) transistors, multi-bridge channel (MBC) transistors, or any transistors having the gate electrode surrounding the channels. The use of the first semiconductor layers 106 to define a channel or channels of the semiconductor device structure 100 is further discussed below.

Each first semiconductor layer 106 may have a thickness in a range between about 3 nm and about 20 nm. Each second semiconductor layer 108 may have a thickness that is equal, less, or greater than the thickness of the first semiconductor layer 106. In some embodiments, each second semiconductor layer 108 has a thickness in a range between about 4 nm and about 30 nm. Three first semiconductor layers 106 and three second semiconductor layers 108 are alternately arranged as illustrated in FIG. 1, which is for illustrative purposes and not intended to be limiting beyond what is specifically recited in the claims. It can be appreciated that any number of first and second semiconductor layers 106, 108 can be formed in the stack of semiconductor layers 104, and the number of layers depending on the predetermined number of channels for the semiconductor device structure 100. In some embodiments, the number of first semiconductor layers 106 ranges from two to 10.

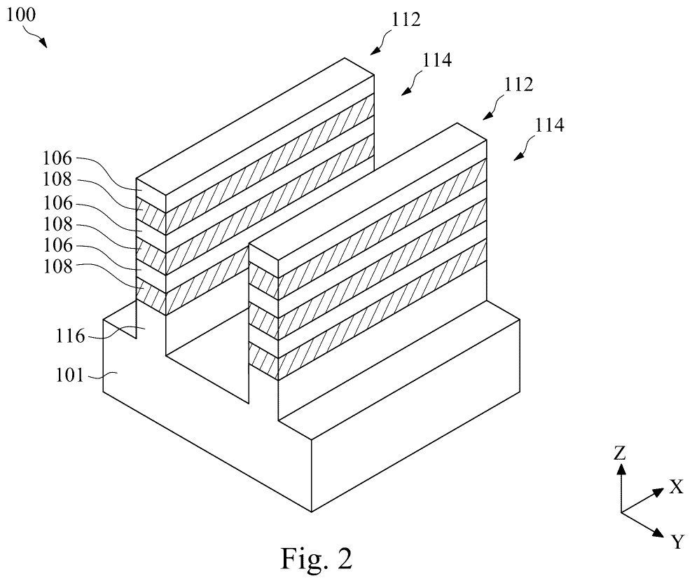

In FIG. 2, fin structures 112 are formed from the stack of semiconductor layers 104. Each fin structure 112 has an upper portion including the semiconductor layers 106, 108 and a substrate portion 116 formed from the substrate 101. The fin structures 112 may be formed by patterning a hard mask layer (not shown) formed on the stack of semiconductor layers 104 using multi-patterning operations including photo-lithography and etching processes. The etching process can include dry etching, wet etching, reactive ion etching (RIE), and/or other suitable processes. The photo-lithography process may include forming a photoresist layer (not shown) over the hard mask layer, exposing the photoresist layer to a pattern, performing post-exposure bake processes, and developing the photoresist layer to form a masking element including the photoresist layer. In some embodiments, patterning the photoresist layer to form the masking element may be performed using an electron beam (e-beam) lithography process. The etching process forms trenches 114 in unprotected regions through the hard mask layer, through the stack of semiconductor layers 104, and into the substrate 101, thereby leaving the plurality of extending fin structures 112. The trenches 114 extend along the X direction. The trenches 114 may be etched using a dry etch (e.g., RIE), a wet etch, and/or combination thereof.

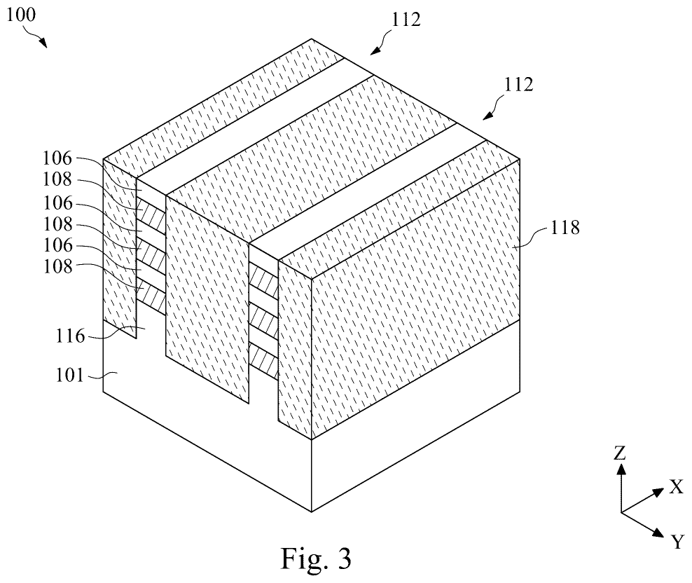

In FIG. 3, after the fin structures 112 are formed, an insulating material 118 is formed on the substrate 101. The insulating material 118 fills the trenches 114 between neighboring fin structures 112 until the fin structures 112 are embedded in the insulating material 118. Then, a planarization operation, such as a chemical mechanical polishing (CMP) method and/or an etch-back method, is performed such that the top of the fin structures 112 is exposed. The insulating material 118 may be made of silicon oxide, silicon nitride, silicon oxynitride (SiON), SiOCN, SiCN, fluorine-doped silicate glass (FSG), a low-K dielectric material, or any suitable dielectric material. The insulating material 118 may be formed by any suitable method, such as low-pressure chemical vapor deposition (LPCVD), plasma enhanced CVD (PECVD) or flowable CVD (FCVD).

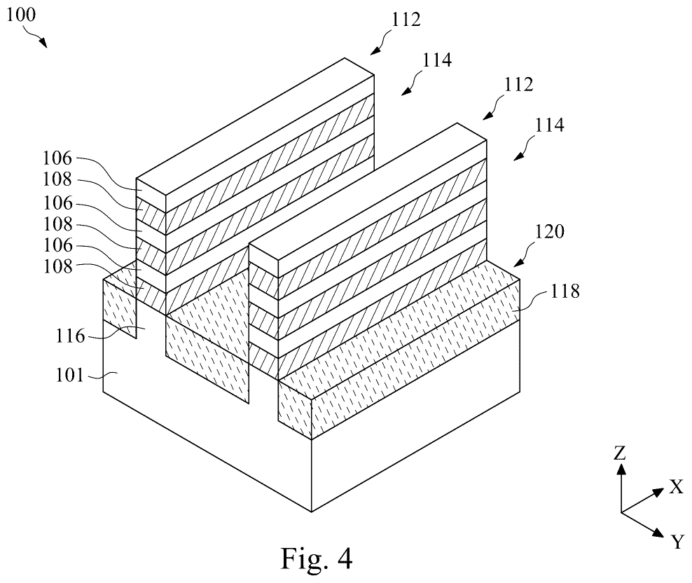

In FIG. 4, the insulating material 118 is recessed to form isolation regions 120. The recess of the insulating material 118 exposes portions of the fin structures 112, such as the stack of semiconductor layers 104. The recess of the insulating material 118 reveals the trenches 114 between the neighboring fin structures 112. The isolation regions 120 may be formed using a suitable process, such as a dry etching process, a wet etching process, or a combination thereof. A top surface of the insulating material 118 may be level with or below a surface of the second semiconductor layers 108 in contact with the substrate portion 116 formed from the substrate 101.

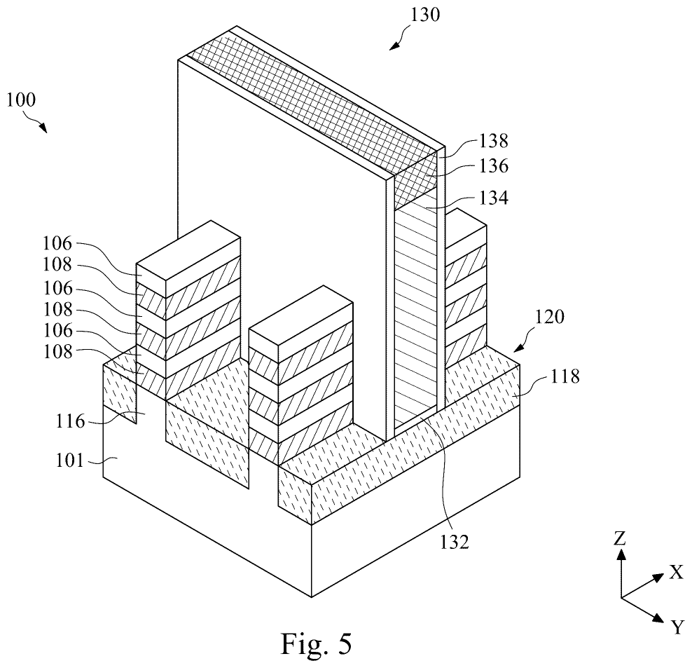

In FIG. 5, one or more sacrificial gate structures 130 (only one is shown) are formed over the semiconductor device structure 100. The sacrificial gate structures 130 are formed over a portion of the fin structures 112. Each sacrificial gate structure 130 may include a sacrificial gate dielectric layer 132, a sacrificial gate electrode layer 134, and a mask layer 136. The sacrificial gate dielectric layer 132, the sacrificial gate electrode layer 134, and the mask layer 136 may be formed by sequentially depositing blanket layers of the sacrificial gate dielectric layer 132, the sacrificial gate electrode layer 134, and the mask layer 136, and then patterning those layers into the sacrificial gate structures 130. Gate spacers 138 are then formed on sidewalls of the sacrificial gate structures 130. The gate spacers 138 may be formed by conformally depositing one or more layers for the gate spacers 138 and anisotropically etching the one or more layers, for example. In some embodiments, the gate spacers 138 are also formed on sidewalls of the exposed portions of the fin structures 112. While one sacrificial gate structure 130 is shown, two or more sacrificial gate structures 130 may be arranged along the X direction in some embodiments.

The sacrificial gate dielectric layer 132 may include one or more layers of dielectric material, such as a silicon oxide-based material. The sacrificial gate electrode layer 134 may include silicon such as polycrystalline silicon or amorphous silicon. The mask layer 136 may include more than one layer, such as an oxide layer and a nitride layer. The gate spacer 138 may be made of a dielectric material such as silicon oxide, silicon nitride, silicon carbide, silicon oxynitride, SiCN, silicon oxycarbide, SiOCN, and/or combinations thereof.

The portions of the fin structures 112 that are covered by the sacrificial gate electrode layer 134 of the sacrificial gate structure 130 serve as channel regions for the semiconductor device structure 100.

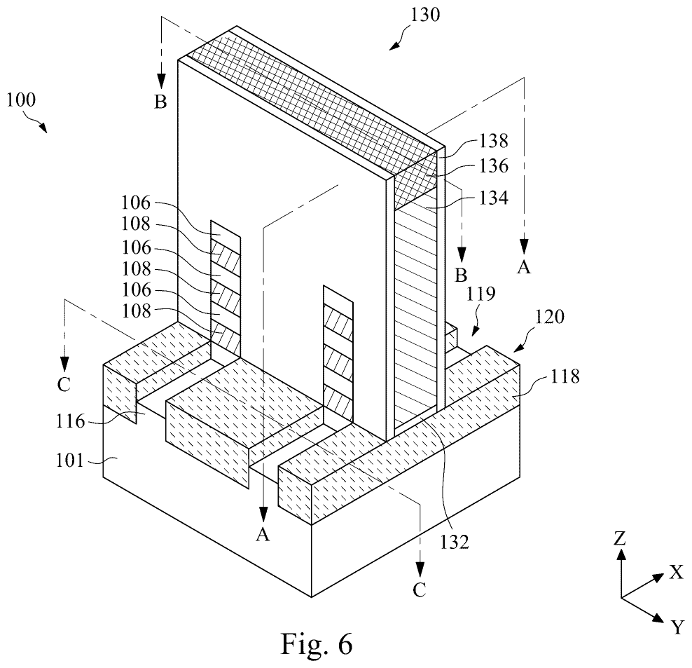

In FIG. 6, the portions of the fin structures 112 not covered by the sacrificial gate structure 130 and the gate spacers 138 are recessed to a level above, at, or below the top surfaces of the isolation regions 120. The recess of the portions of the fin structures 112 can be done by an etch process, either isotropic or anisotropic etch process, and the etch process may be selective with respect to the first and second semiconductor layers 106, 108. The etch process may be a dry etch, such as a RIE, NBE, or the like, or a wet etch, such as using tetramethyalammonium hydroxide (TMAH), ammonium hydroxide (NH₄OH), or any suitable etchant.

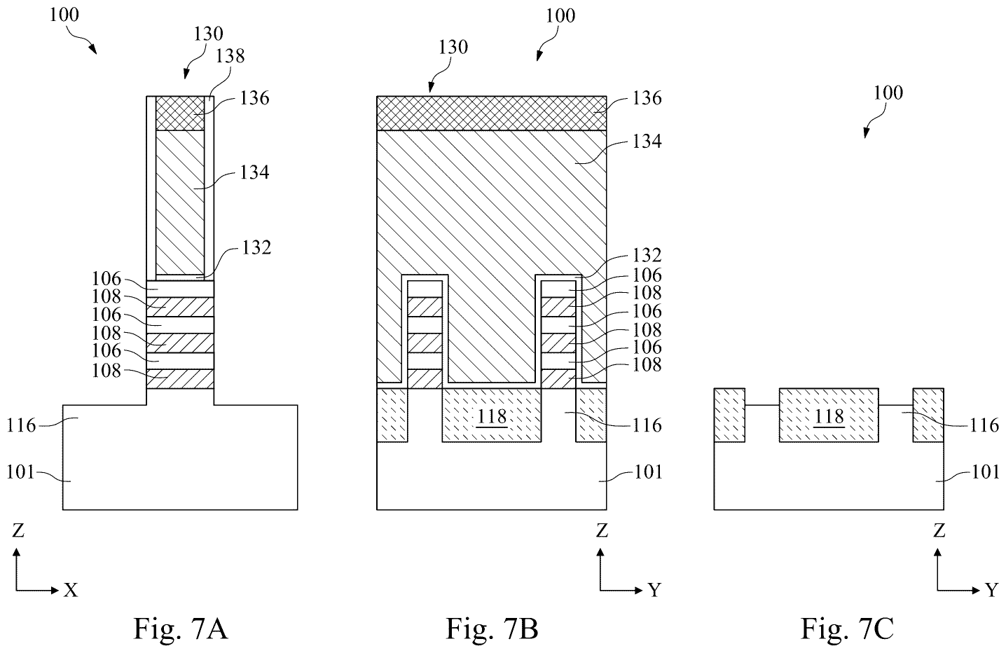

FIGS. 7A, 7B, and 7C are cross-sectional side views of the semiconductor device structure 100 taken along line A-A, line B-B, and line C-C of FIG. 6, respectively.

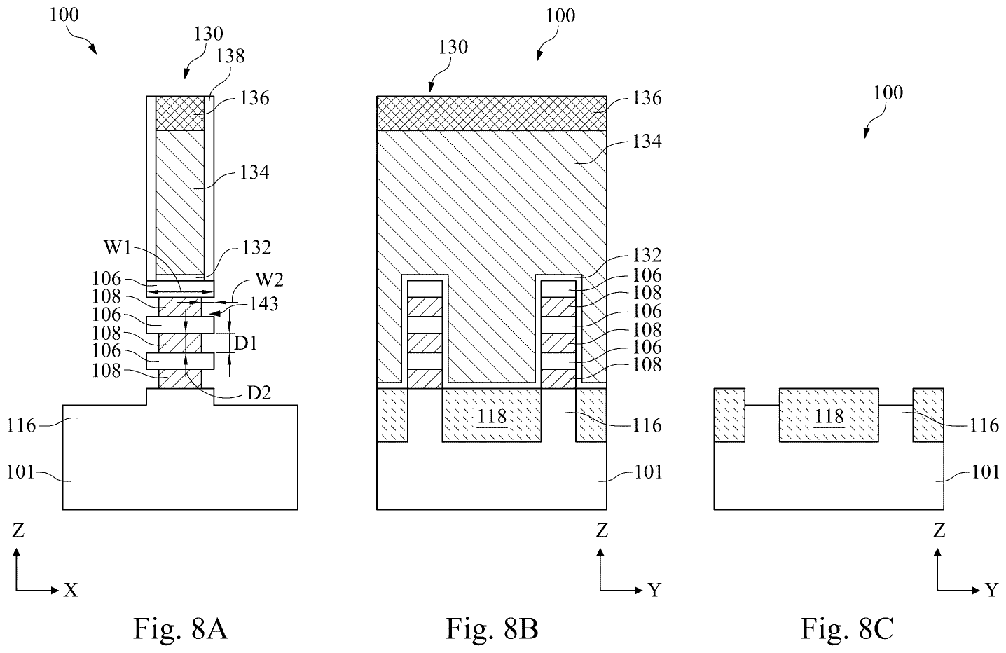

FIGS. 8A, 8B, and 8C are cross-sectional side views of one of various stages of manufacturing the semiconductor device structure 100 taken along line A-A, line B-B, and line C-C of FIG. 6, respectively, in accordance with some embodiments. As shown in FIG. 8A, edge portions of each second semiconductor layer 108 of the stack of semiconductor layers 104 are removed horizontally along the X direction. The removal of the edge portions of the second semiconductor layers 108 forms cavities 143. In some embodiments, the portions of the second semiconductor layers 108 are removed by a selective wet etch process. In cases where the second semiconductor layers 108 are made of SiGe and the first semiconductor layers 106 are made of silicon, the second semiconductor layer 108 can be selectively etched using a wet etchant such as, but not limited to, ammonium hydroxide (NH₄OH), tetramethylammonium hydroxide (TMAH), ethylenediamine pyrocatechol (EDP), or potassium hydroxide (KOH) solutions. In some embodiments, each cavity 143 has a first dimension D1 defined by the distance between corners of vertically adjacent first semiconductor layers 106. The corner of the first semiconductor layer 106 is the connecting point of the outer edge and the top surface (or the bottom surface) of the first semiconductor layer 106. Each cavity 143 has a second dimension D2 defined by the thickness of the second semiconductor layer 108. In some embodiments, the first dimension D1 and the second dimension D2 are substantially the same, as shown in FIG. 8A. In other words, the cavity 143 has a rectangular cross section, as shown in FIG. 8A. In some embodiments, the dimension D2 may have a curved profile. In some embodiments, the dimensions D1 and D2 are the width of the cavity 143, and the width is substantially constant. In some embodiments, the first semiconductor layer 106 has a width W1, and the cavity 143 has a depth W2. The width W1 may range from about 15 nm to about 100 nm, and the depth W2 may range from about 3 nm to about 20 nm. In some embodiments, a ratio of the depth W2 to the width W1 may range from about 1:2 to about 1:10. In some embodiments, a ratio of the depth W2 to the dimension D2 may range from about 1:5 to about 5:1.

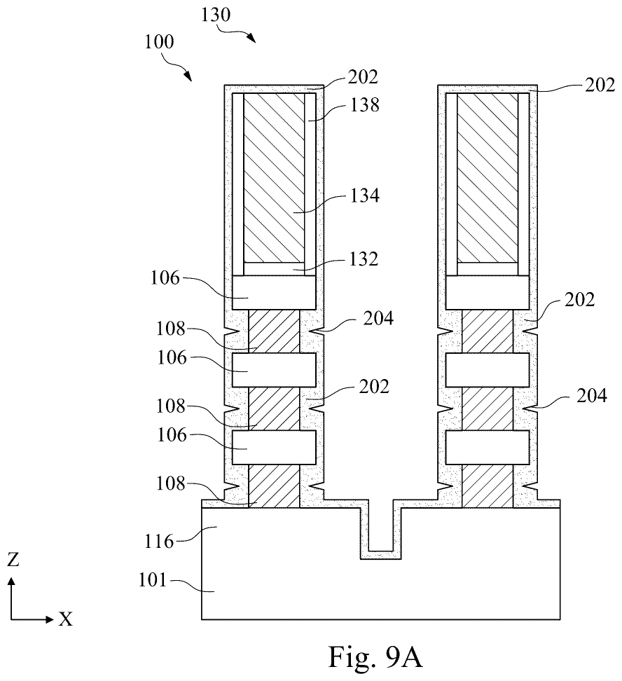

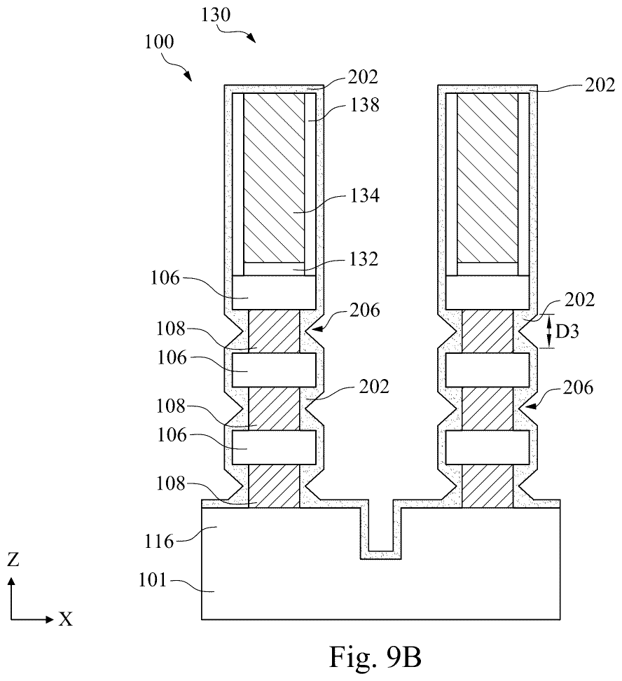

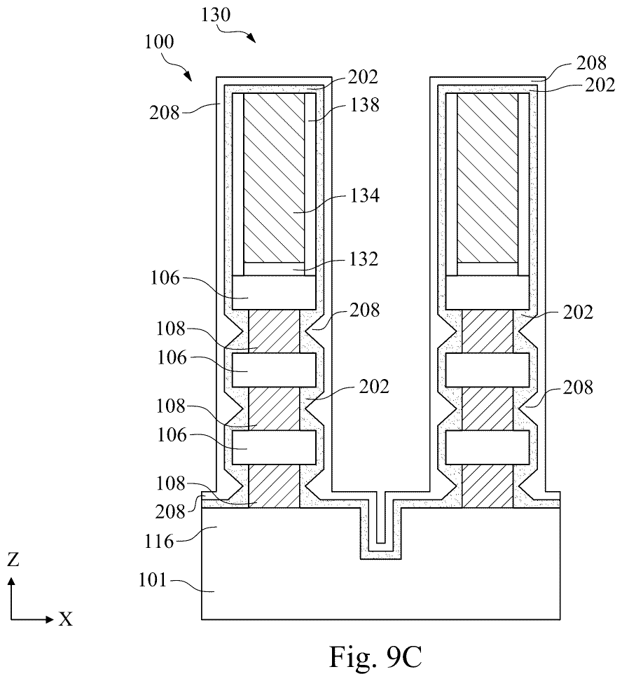

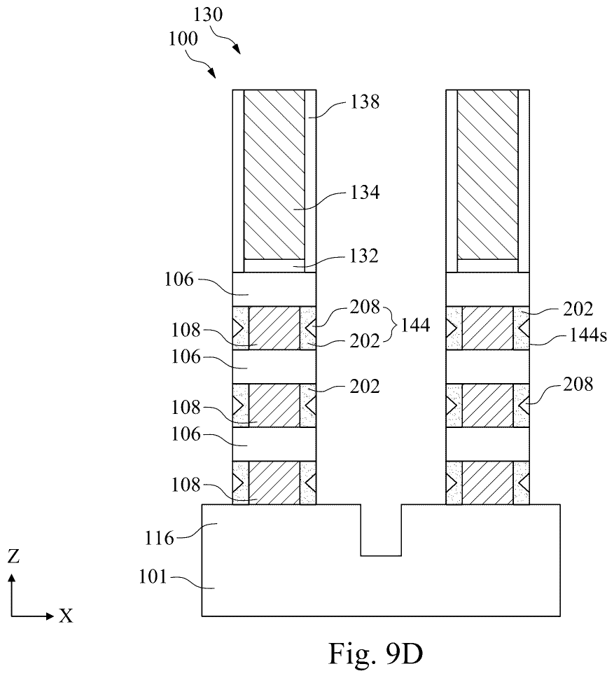

FIGS. 9A-9D are cross-sectional side views of various stages of manufacturing the semiconductor device structure 100, in accordance with some embodiments. The mask layer 136 is omitted in FIGS. 9A-9D for clarity. As shown in FIG. 9A, a first spacer layer 202 is deposited on the surface of the semiconductor device structure 100. The first spacer layer 202 substantially fills the cavities 143 formed by the removal of the edge portions of the second semiconductor layers 108. The first spacer layer 202 may include any suitable dielectric material. For example, in some embodiments, the first spacer layer 202 includes a silicon based low-k dielectric material, such as SION, SiCN, SiOC, SiOCN, or SiN. In some embodiments, the first spacer layer 202 is made of or includes SiCₓO_{y}N_{z}, where x, y, and z are integers or non-integers. The first spacer layer 202 may be deposited by any suitable process. In some embodiments, the first spacer layer 202 is a conformal layer formed by a conformal process, such as an ALD process. In some embodiments, a scam 204 is formed in the portions of the first spacer layer 202 formed in the cavities 143 between vertically adjacent first semiconductor layers 106, as shown in FIG. 9A. The seam 204 may be a result of the ALD process to form the first spacer layer 202. In some embodiments, the first spacer layer 202 has a thickness ranging from about 5 nm to about 10 nm. If the thickness of the first spacer layer 202 is less than about 5 nm, the cavities 143 would not be filled. On the other hand, if the thickness of the first spacer layer 202 is greater than about 10 nm, it would be more difficult to remove portions of the first spacer layer 202 formed outside of the cavities 143.

As shown in FIG. 9B, one or more etch processes are performed to form an opening 206 in a portion of the first spacer layer 202 located in each cavity 143 (FIG. 8A). In some embodiments, an isotropic etch process is performed to form the openings 206. The isotropic etch process may be a dry etch process or a wet etch process. In some embodiments, the isotropic etch process is performed for a short period of time to ensure that the second semiconductor layers 108 are not exposed. For example, the isotropic etch process is performed for a time period ranging from about 10 seconds to about 500 seconds. The isotropic etch process also removes portions of the first spacer layer 202 disposed outside of the cavities 143 (FIG. 8A). As a result, the thickness of the first spacer layer 202 formed around the sacrificial gate structures 130 and on the substrate portion 116 is reduced.

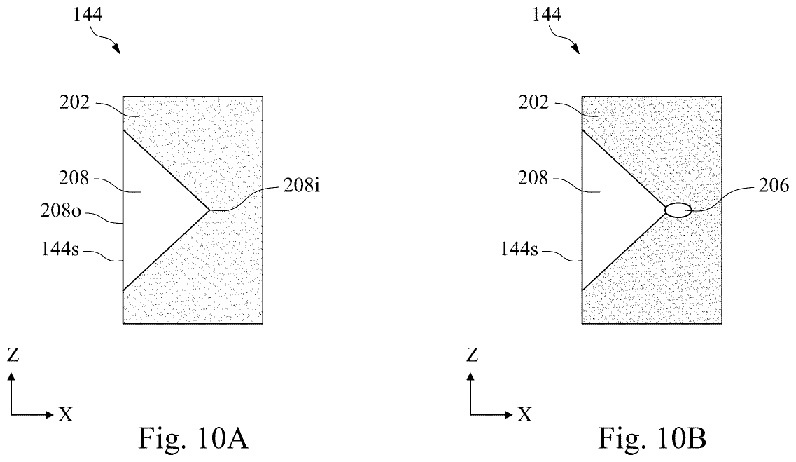

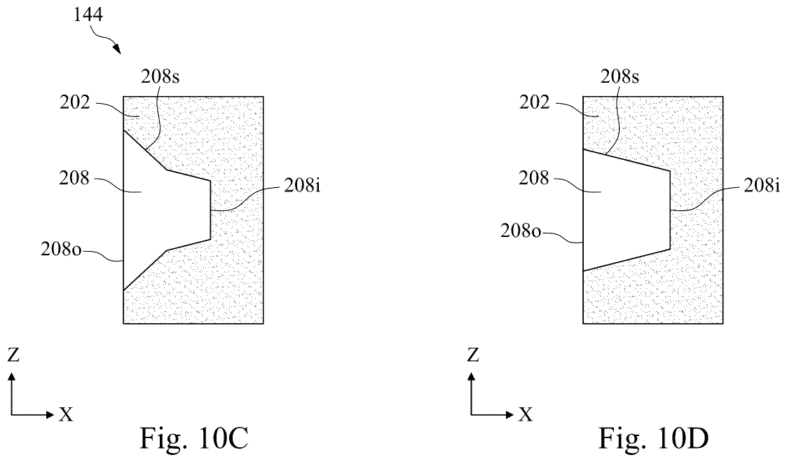

The opening 206 has a dimension D3, which is the width of the opening 206. In some embodiments, the width of the opening 206 decreases in a direction towards the second semiconductor layer 108, as shown in FIG. 9B. The opening 206 may have any shaped cross section with the width decreasing in the direction towards the second semiconductor layer 108. In some embodiments, the opening 206 has a triangular cross section, as shown in FIG. 9B. In some embodiments, the opening 206 has a trapezoidal cross section, as shown in FIG. 10D. In some embodiments, the sidewalls (i.e., the top and bottom surfaces defining the opening 206 as shown in FIG. 9B) of the opening 206 are not linear, such as curved or having different angles with respect to a plane defined by a bottom surface of the substrate 101. The cross-sectional shape of the opening 206 ensures that the opening 206 is filled with the subsequently deposited second spacer layer 208 without forming a seam. In some embodiments, the seams 204 (FIG. 9A) are exposed to the opening 206 and become part of the opening 206.

As shown in FIG. 9C, the second spacer layer 208 is deposited on the first spacer layer 202. The second spacer layer 208 may include any suitable material. In some embodiments, the second spacer layer 208 includes the same material as the first spacer layer 202. For example, the first and second spacer layer 208 both include or are made of SiCₓO_{y}N_{z}. In some embodiments, the second spacer layer 208 includes a different material from the first spacer layer 202. For example, the first spacer layer 202 includes or is made of a silicon based dielectric material, such as SiCₓO_{y}N_{z}, and the second spacer layer 208 includes or is made of a boron based dielectric material, such as BCₓO_{y}N_{z}. The k value of SiCₓO_{y}N_{z} may range from about 3 to about 6, and the k value of BCₓO_{y}N_{z} may range from about 2 to about 6. The second spacer layer 208 may be deposited by any suitable process, such as ALD, CVD, or FCVD. In some embodiments, the second spacer layer 208 is deposited by ALD or FCVD, and the second spacer layer 208 fills the openings 206 without forming seams due to the shape of the openings 206. In some embodiments, the second spacer layer 208 is deposited by CVD, and seams may be formed in the second spacer layer 208 in the openings 206. In some embodiments, the opening 206 is not completely filled, and a portion of the opening 206 remains between the first spacer layer 202 and the second spacer layer 208. In some embodiments, the second spacer layer 208 includes two or more layers.

As shown in FIG. 9D, one or more etch processes are performed to remove the portions of the second spacer layer 208 and portions of the first spacer layer 202 located outside of the cavities 143 (FIG. 8A). As a result, dielectric spacers 144, which include the first spacer layer 202 and the second spacer layer 208, are formed in the cavities 143 (FIG. 8A). The second semiconductor layers 108 are capped between the dielectric spacers 144 along the X direction.

In some embodiments, the first and second spacer layers 202, 208 are made of the same material, and a single etch process is performed to remove the portions of the first and second spacer layers 202, 208. The single etch process may be an anisotropic etch process, and the portions of the first and second spacer layers 202, 208 formed in the cavities 143 are protected by the first semiconductor layers 106 during the anisotropic etch process. In some embodiments, the first and second spacer layers 202, 208 are made of different materials. A first etch process is performed to remove the portions of the second spacer layer 208 disposed outside of the cavities 143, and a second etch process is performed to remove the portions of the first spacer layer 202. The first and second etch processes may be anisotropic etch processes. The first and second etch processes can lead to substantially straight sidewalls 144s of the dielectric spacers 144 due to the different etch selectivity.

In some embodiments, the first spacer layer 202 is made of SiCₓO_{y}N_{z}, the second spacer layer 208 is made of BCₓO_{y}N_{z}, and a single etch process may be performed to remove the portions of the first and second spacer layers 202, 208. For example, a dry anisotropic etch process using a fluorine-based etchant, such as CF₄, is performed. The etch rate of the second spacer layer 208 is substantially slower than the etch rate of the first spacer layer 202. In other words, the second spacer layer 208 has a high etching resistance during the removal of the portions of the first and second spacer layers 202, 208. As a result, sidewalls 144s of the dielectric spacers 144 are substantially straight and are substantially aligned with the sidewalls of the first semiconductor layers 106. In some embodiments, without the high etching resistant second spacer layer 208, the sidewalls 144s may be recessed, which may lead to electric short between the subsequently formed gate electrode layer 172 and the source/drain regions 146. In some embodiments, a ratio of the etch rate of the first spacer layer 202 to the etch rate of the second spacer layer 208 may range from about 1:10 to about 10:1. In some embodiments, the ratio of the etch rate of the first spacer layer 202 to the etch rate of the second spacer layer 208 ranges from about 2:1 to about 10:1

FIGS. 10A-10D are cross-sectional side views of the dielectric spacer 144 of the semiconductor device structure 100, in accordance with some embodiments. As shown in FIG. 10A, the opening 206 (FIG. 9B) has a triangular cross section, and the second spacer layer 208 has a triangular cross section. In some embodiments, the opening 206 is completely filled with the second spacer layer 208. The one or more etch processes to remove portions of the first and second spacer layers 202, 208 can lead to the substantially straight sidewall 144s. In some embodiments, as shown in FIG. 10A, the second spacer layer 208 includes an outer edge 208o and an inner edge 208i. In some embodiments, the outer edge 208o may be substantially straight and the inner edge 208i may be a point. Thus, in some embodiments, the length of the outer edge 208o along the Z direction is substantially greater than the length of the inner edge 208i.

In some embodiments, as shown in FIG. 10B, the opening 206 is not completely filled with the second spacer layer 208, and a small portion of the opening 206 remains between the first and second spacer layers 202, 208, as shown in FIG. 10B. In some embodiments, the process to deposit the second spacer layer 208 is chosen to have poor gap filling capability in order to create the small portion of the opening 206 between the first and second spacer layers 202, 208, because the opening 206 has a smaller k value compared to the first and second spacer layers 202, 208. As a result, capacitance is reduced.

In some embodiments, the opening 206 (FIG. 9B) has a trapezoidal cross section with non-linear sidewalls, and the second spacer layer 208 has a trapezoidal cross section with non-linear sidewalls 208s, as shown in FIG. 10C. For example, the second spacer layer 208 has an outer edge 208o, an inner edge 208i, and sidewalls 208s connecting the outer edge 208o and the inner edge 208i. In some embodiments, the outer edge 208o and the inner edge 208i are substantially straight and are substantially parallel to each other, as shown in FIG. 10C. In some embodiments, the length of the outer edge 208o along the Z direction is substantially greater than the length of the inner edge 208i, as shown in FIG. 10C. The sidewall 208s may be a curved sidewall or a sidewall having multiple angles with respect to the plane defined by the bottom surface of the substrate 101. In some embodiments, the opening 206 (not shown) is formed between the first and second spacer layers 202, 208.

In some embodiments, the opening 206 (FIG. 9B) has a trapezoidal cross section with linear sidewalls, and the second spacer layer 208 has a trapezoidal cross section with linear sidewalls 208s, as shown in FIG. 10D. In some embodiments, the outer edge 208o and the inner edge 208i are substantially straight and are substantially parallel to each other, as shown in FIG. 10D. In some embodiments, the length of the outer edge 208o along the Z direction is substantially greater than the length of the inner edge 208i, as shown in FIG. 10D. In some embodiments, the opening 206 (not shown) is formed between the first and second spacer layers 202, 208.

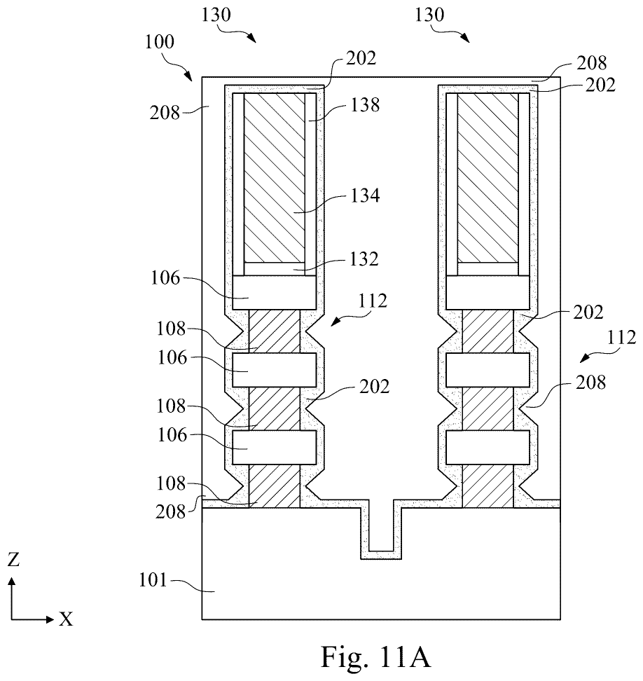

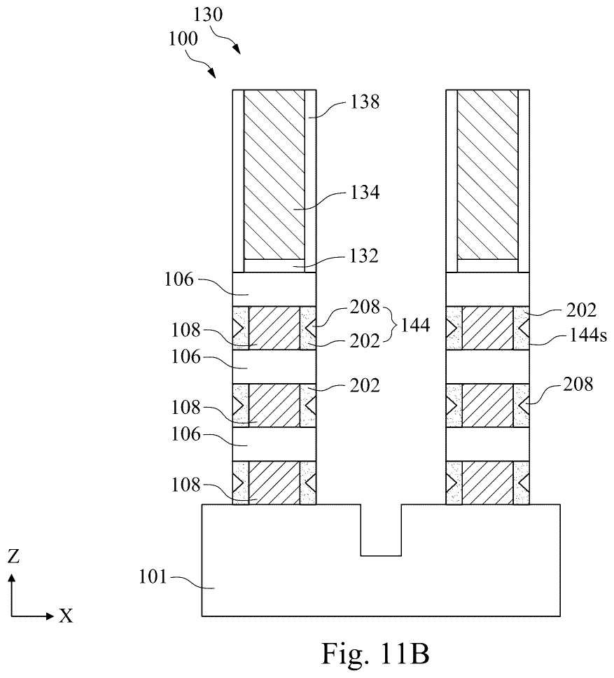

FIGS. 11A and 11B are cross-sectional side views of various stages of manufacturing the semiconductor device structure 100, in accordance with alternative embodiments. As shown in FIG. 11A, the second spacer layer 208 is deposited by an FCVD process. Unlike the second spacer layer 208 shown in FIG. 9C, the second spacer layer 208 fills the space between adjacent fin structures 112 and adjacent sacrificial gate structures 130. The second spacer layer 208 formed by the FCVD process may have improved gap filling property. As a result, the openings 206 are filled. The as-deposited second spacer layer 208 may be in liquid form, and a thermal process may be performed to cure the as-deposited second spacer layer 208. The thermal process may be an annealing process performed at a temperature ranging from about 200 degrees Celsius to about 1100 degrees Celsius. The curing of the as-deposited second spacer layer 208 may lead to intermixing of the first and second spacer layers 202, 208. In some embodiments, the first and second spacer layers 202, 208 include different materials, and the dielectric spacer 144 includes the first spacer layer 202, the second spacer layer 208, and a third material located at the interface between the first and second spacer layers 202, 208. In some embodiments, the first spacer layer 202 is made of SiCₓO_{y}N_{z}, the second spacer layer 208 is made of BCₓO_{y}N_{z}, and the third material includes SiBCₓO_{y}N_{z}.

After the thermal process, a planarization process is performed to remove the portions of the first and second spacer layers 202, 208 formed on the sacrificial gate structures 130 to expose the sacrificial gate electrode layers 134. Next, a selective etch process is performed to remove the portions of the second spacer layer 208 located outside of the openings 206 (FIG. 9B). Materials of the semiconductor device structure 100 other than the second spacer layer 208 may not be substantially affected by the selective etch process. The selective etch process may be an anisotropic etch process. As a result, the portions of the second spacer layer 208 located in the openings 206 are protected by the first spacer layer 202. After removing the portions of the second spacer layer 208, a second selective etch process is performed to remove the portions of the first spacer layer 202 located outside of the cavities 143 (FIG. 8A). Materials of the semiconductor device structure 100 other than the first spacer layer 202 may not be substantially affected by the second selective etch process. The second selective etch process may be an anisotropic etch process. As a result, the portions of the first spacer layer 202 located in the cavities 143 are protected by the first semiconductor layers 106, as shown in FIG. 11B.

In some embodiments, the first and second spacer layers 202, 208 include the same material, and a single anisotropic selective etch process may be performed to remove portions of the first and second spacer layers 202, 208 located outside of the cavities 143 (FIG. 8A). Materials of the semiconductor device structure 100 other than the first and second spacer layers 202, 208 may not be substantially affected by the single anisotropic selective etch process. The portions of the first and second spacer layers 202, 208 located in the cavities 143 (i.e., the dielectric spacers 144) are protected by the first semiconductor layers 106 during the single anisotropic selective etch process.

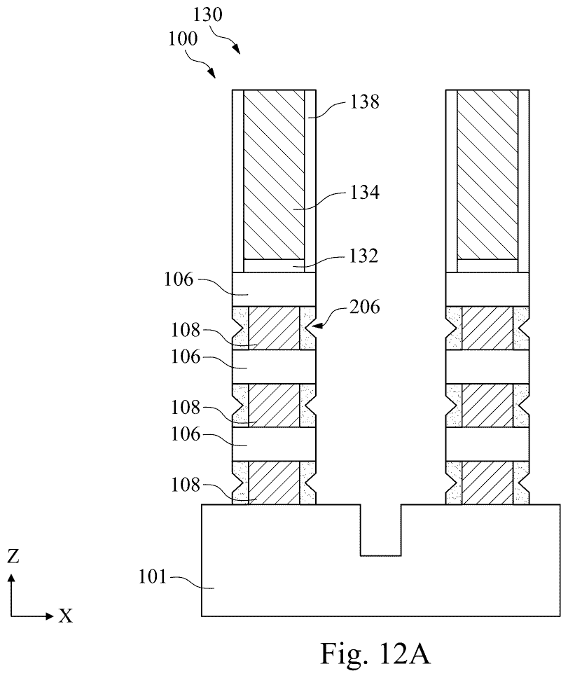

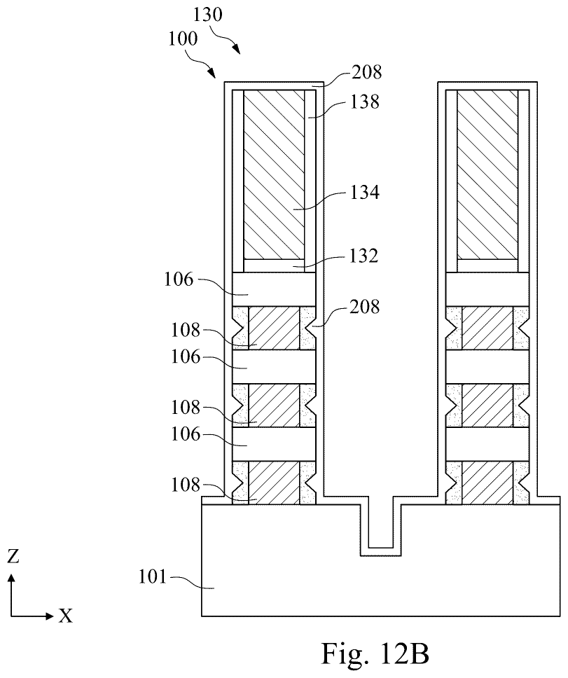

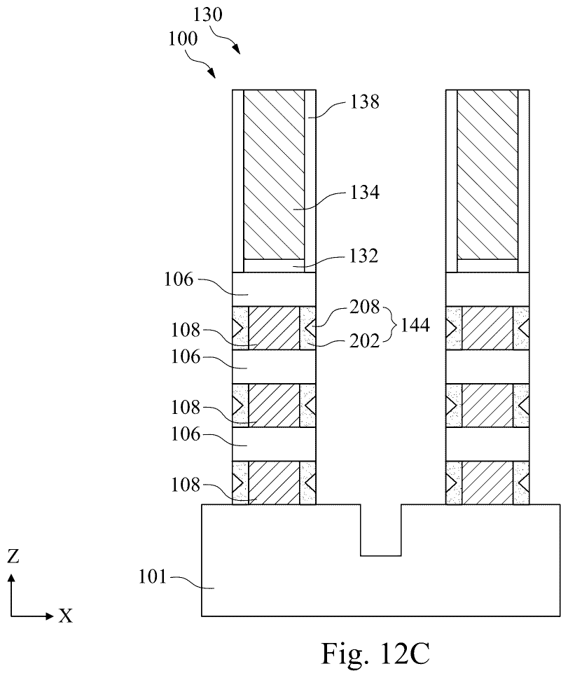

FIGS. 12A-12C are cross-sectional side views of various stages of manufacturing the semiconductor device structure 100, in accordance with alternative embodiments. As shown in FIG. 12A, after the formation of the first spacer layer 202 as shown in FIG. 9A, two or more etch processes are performed to remove portions of the first spacer layer 202 located outside of the cavities 143 (FIG. 8A). In some embodiments, an anisotropic etch process is performed to remove portions of the first spacer layer 202 located outside of the cavities 143, and an isotropic etch process is performed to form the openings 206. The anisotropic etch process may be performed before or after the isotropic etch process. In some embodiments, a single etch process is performed to form the first spacer layer 202 as shown in FIG. 12A. The single etch process may include a first time period with a bias power applied to the substrate support holding the semiconductor device structure 100 and a second time period without applying the bias power. The first time period of the single etch process may be anisotropic, and the second time period of the single etch process may be isotropic. In some embodiments, in order to remove the portions of the first spacer layer 202 located outside of the cavities 143, the first time period is substantially longer than the second time period. The two or more etch processes or the single etch process to remove portions of the first spacer layer 202 located outside of the cavities 143 may be selective. As a result, other components of the semiconductor device structure 100 are not substantially affected.

As shown in FIG. 12B, the second spacer layer 208 is deposited in the openings 206 and on other components of the semiconductor device structure 100. Next, as shown in FIG. 12C, the portions of the second spacer layer 208 located outside of the openings 206 are removed, and the dielectric spacers 144 are formed. The portions of the second spacer layer 208 located outside of the openings 206 may be removed by a selective anisotropic etch process. The dielectric spacers 144 (i.e., the first and second spacer layers 202, 208 located in the cavities 143) are protected by the first semiconductor layers 106 during the selective anisotropic etch process.

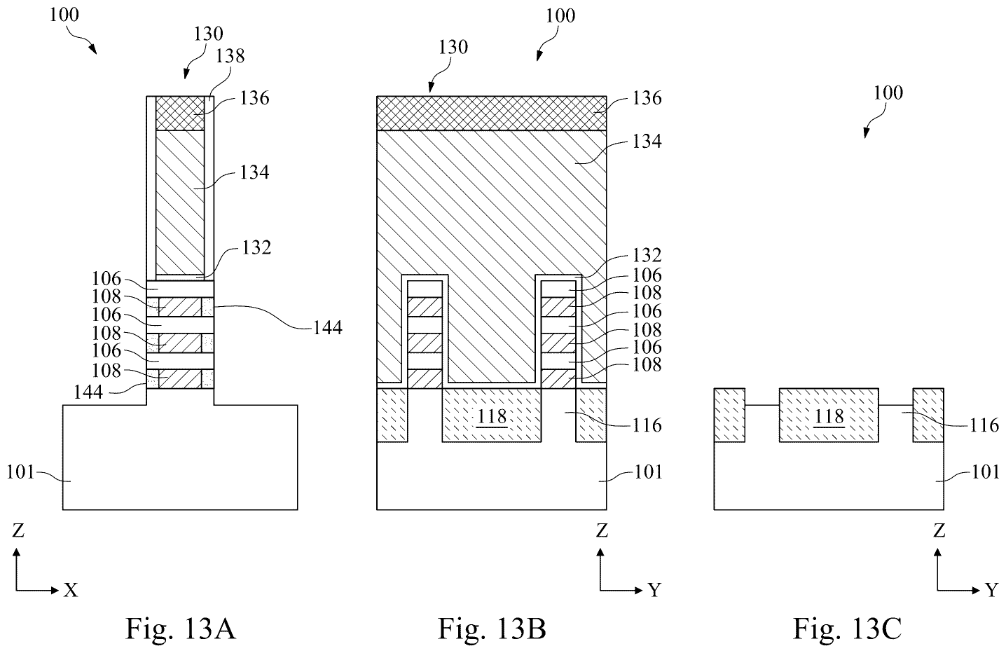

FIGS. 13A-16A are cross-sectional side views of various stages of manufacturing the semiconductor device structure taken along line A-A of FIG. 6, in accordance with some embodiments. FIGS. 13B-16B are cross-sectional side views of various stages of manufacturing the semiconductor device structure taken along line B-B of FIG. 6, in accordance with some embodiments. FIGS. 13C-16C are cross-sectional side views of various stages of manufacturing the semiconductor device structure taken along line C-C of FIG. 6, in accordance with some embodiments. FIGS. 13A, 13B, and 13C are cross-sectional side views of the semiconductor device structure 100 after the formation of the dielectric spacers 144. The first and second spacer layers 202, 208 of the dielectric spacers 144 are omitted in FIGS. 13A-16C for clarity.

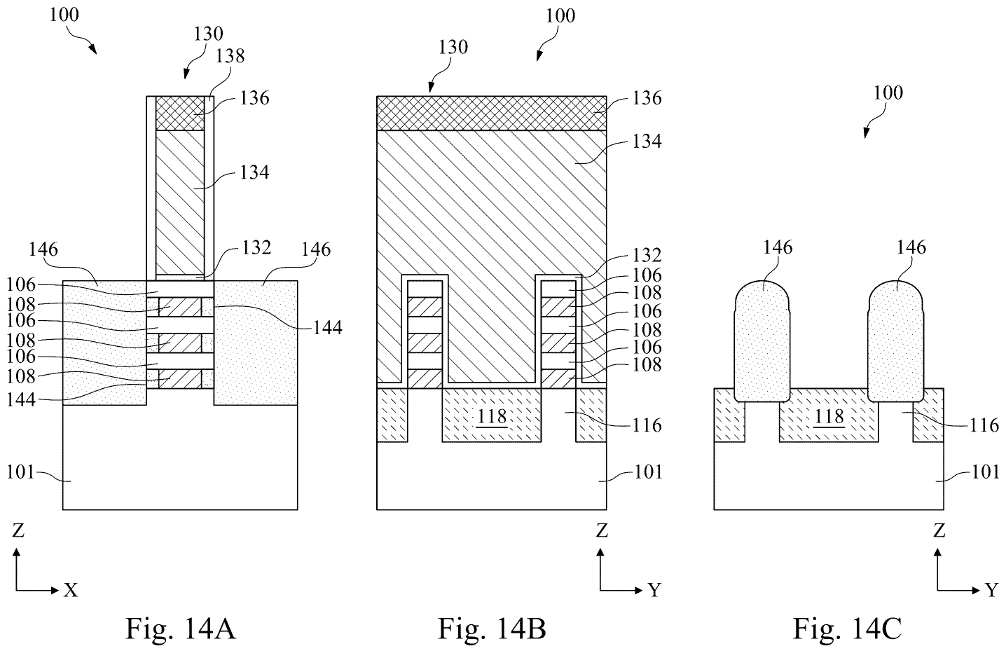

As shown in FIGS. 14A and 14C, source/drain (S/D) regions 146 are formed from the substrate portion 116. The S/D regions 146 may grow both vertically and horizontally to form facets, which may correspond to crystalline planes of the material used for the substrate portion 116. In this disclosure, a source region and a drain region are interchangeably used, and the structures thereof are substantially the same. Furthermore, source/drain region(s) may refer to a source or a drain, individually or collectively dependent upon the context. The S/D regions 146 may be made of one or more layers of Si, SiP, SiC and SiCP for n-channel FETs or Si, SiGe, Ge for p-channel FETs. For p-channel FETs, p-type dopants, such as boron (B), may also be included in the S/D regions 146. The S/D regions 146 may be formed by an epitaxial growth method using CVD, ALD or MBE. In some embodiments, the S/D regions 146 may be formed at an elevated temperature, and the first and second spacer layers 202, 208 may intermix at the elevated temperature. As a result, a third material may be formed at the interface between the first and second spacer layers 202, 208. The third material may be the third material described in FIGS. 11A and 11B.

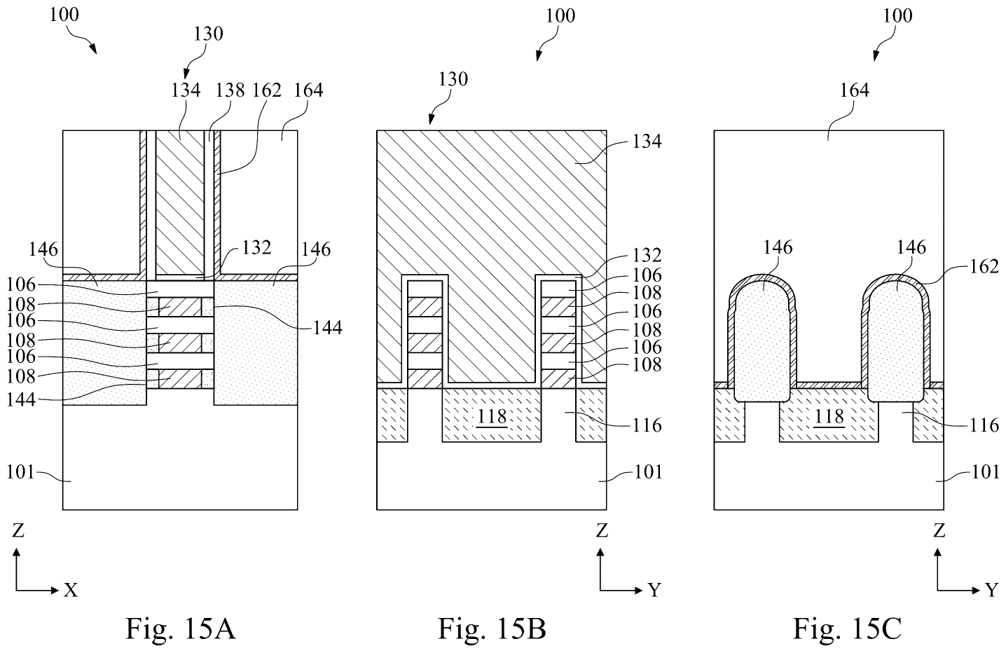

Next, as shown in FIGS. 15A, 15B, and 15C, a contact etch stop layer (CESL) 162 is conformally formed on the exposed surfaces of the semiconductor device structure 100. The CESL 162 covers the sidewalls of the sacrificial gate structure 130, the insulating material 118, and the S/D regions 146. The CESL 162 may include an oxygen-containing material or a nitrogen-containing material, such as silicon nitride, silicon carbon nitride, silicon oxynitride, carbon nitride, silicon oxide, silicon carbon oxide, or the like, or a combination thereof, and may be formed by CVD, PECVD, ALD, or any suitable deposition technique. Next, an interlayer dielectric (ILD) layer 164 is formed on the CESL 162 over the semiconductor device structure 100. The materials for the ILD layer 164 may include compounds including Si, O, C, and/or H, such as silicon oxide, SiCOH, or SiOC. Organic materials, such as polymers, may also be used for the ILD layer 164. The ILD layer 164 may be deposited by a PECVD process or other suitable deposition technique. In some embodiments, after formation of the ILD layer 164, the semiconductor device structure 100 may be subject to a thermal process to anneal the ILD layer 164.

After the ILD layer 164 is formed, a planarization operation, such as CMP, is performed on the semiconductor device structure 100 until the sacrificial gate electrode layer 134 is exposed, as shown in FIGS. 15A and 15B.

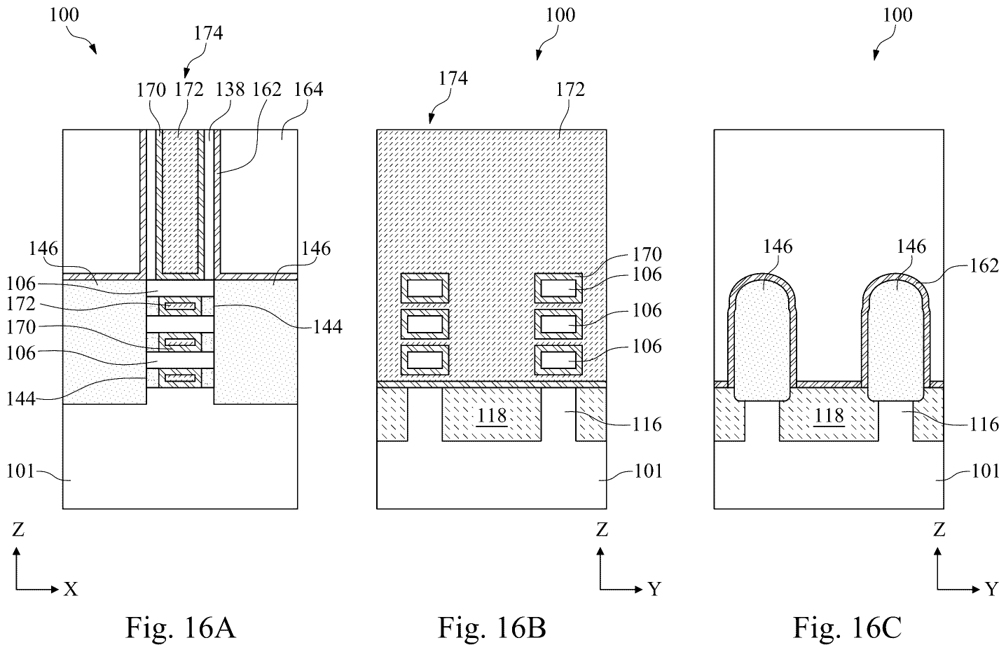

As shown in FIGS. 16A and 16B, the sacrificial gate structure 130 and the second semiconductor layers 108 are removed. The removal of the sacrificial gate structure 130 and the semiconductor layers 108 forms an opening between gate spacers 138 and between first semiconductor layers 106. The ILD layer 164 protects the S/D regions 146 during the removal processes. The sacrificial gate structure 130 can be removed using plasma dry etching and/or wet etching. The sacrificial gate electrode layer 134 may be first removed by any suitable process, such as dry etch, wet etch, or a combination thereof, followed by the removal of the sacrificial gate dielectric layer 132, which may also be performed by any suitable process, such as dry etch, wet etch, or a combination thereof. In some embodiments, a wet etchant such as a tetramethylammonium hydroxide (TMAH) solution can be used to selectively remove the sacrificial gate electrode layer 134 but not the gate spacers 138, the ILD layer 164, and the CESL 162.

The second semiconductor layers 108 may be removed using a selective wet etching process. In cases where the second semiconductor layers 108 are made of SiGe and the first semiconductor layers 106 are made of Si, the chemistry used in the selective wet etching process removes the SiGe while not substantially affecting Si, the dielectric materials of the gate spacers 138, and the dielectric spacers 144. In one embodiment, the second semiconductor layers 108 can be removed using a wet etchant such as, but not limited to, hydrofluoric (HF), nitric acid (HNO₃), hydrochloric acid (HCl), phosphoric acid (H₃PO₄), a dry etchant such as fluorine-based (e.g., F₂) or chlorine-based gas (e.g., Cl₂), or any suitable isotropic etchants.

After the formation of the nanosheet channels (i.e., the exposed first semiconductor layers 106), a gate dielectric layer 170 is formed around each first semiconductor layer 106, and a gate electrode layer 172 is formed on the gate dielectric layer 170, surrounding a portion of each first semiconductor layer 106, as shown in FIGS. 16A and 16B. The gate dielectric layer 170 and the gate electrode layer 172 may be collectively referred to as a gate structure 174. In some embodiments, an interfacial layer (IL) (not shown) is formed between the gate dielectric layer 170 and the exposed surfaces of the first semiconductor layers 106. As shown in FIG. 16A, the gate structure 174 is located between the dielectric spacers 144. In some embodiments, the gate dielectric layer 170 includes one or more layers of a dielectric material, such as silicon oxide, silicon nitride, or high-K dielectric material, other suitable dielectric material, and/or combinations thereof. Examples of high-K dielectric material include HfO₂, HfSiO, HfSiON, HfTaO, HfTiO, HfZrO, zirconium oxide, aluminum oxide, titanium oxide, hafnium dioxide-alumina (HfO2-Al2O3) alloy, other suitable high-K dielectric materials, and/or combinations thereof. The gate dielectric layer 170 may be formed by CVD, ALD or any suitable deposition technique. In one embodiment, the gate dielectric layer 170 is formed using a conformal deposition process such as ALD in order to ensure the formation of a gate dielectric layer having a uniform thickness around each first semiconductor layer 106.

The gate electrode layer 172 is formed on the gate dielectric layer 170 to surround a portion of each first semiconductor layer 106. The gate electrode layer 172 may include one or more layers of conductive material, such as polysilicon, aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, other suitable materials, and/or any combinations thereof. The gate electrode layer 172 may be formed by CVD, ALD, electro-plating, or other suitable deposition technique. The gate electrode layer 172 may be also deposited over the upper surface of the first ILD layer 164. The gate dielectric layer 170 and the gate electrode layer 172 formed over the first ILD layer 164 are then removed by using, for example, CMP, until the top surface of the first ILD layer 164 is exposed.

Embodiments of the present disclosure provide a semiconductor device structure and methods of forming the same. The structure includes a semiconductor layer 106 disposed over a substrate portion 116, a gate structure 174 surrounding a portion of the semiconductor layer 106, and dielectric spacers 144 disposed on the semiconductor layer 106 and on opposite sides of the gate structure 174. In some embodiments, the dielectric spacer 144 includes a first spacer layer 202 and a second spacer layer 208. The second spacer layer 208 includes an outer edge 208o and an inner edge 208i, and the length of the outer edge 208o is substantially greater than the length of the inner edge 208i. Some embodiments may achieve advantages. For example, the shape of the second spacer layer 208 is the result of the shape of the opening 206, which has a dimension that decreases towards a semiconductor layer 108. The shape of the opening 206 can lead to a seam free second spacer layer 208, which may lead to reduced electric short between the gate structure 174 and the S/D regions 146.

An embodiment is a semiconductor device structure. The structure includes a substrate portion extending from a substrate, a semiconductor layer disposed over the substrate portion, a gate structure surrounding at least a portion of the semiconductor layer, and first and second dielectric spacers disposed on the semiconductor layer. A portion of the gate structure is disposed between the first and second dielectric spacers, and each of the first and second dielectric spacer includes a first spacer layer and a second spacer layer disposed adjacent the first spacer layer. The second spacer layer has an outer edge and an inner edge, and a length of the outer edge is substantially greater than a length of the inner edge.

Another embodiment is a method. The method includes forming a fin structure from a substrate, and the fin structure includes a first semiconductor layer and a second semiconductor layer. The method further includes removing an edge portion of the second semiconductor layer to form a cavity and forming a dielectric spacer in the cavity. The forming of the dielectric spacer includes depositing a first spacer layer, and a first portion of the first spacer layer is deposited in the cavity. The forming of the dielectric spacer further includes performing a first etch process to form an opening in the first portion of the first spacer layer, and the opening has a dimension that decreases in a direction towards the second semiconductor layer. The forming of the dielectric spacer further includes depositing a second spacer layer, and a first portion of the second spacer layer is deposited in the opening.

A further embodiment is a method. The method includes forming a fin structure from a substrate, and the fin structure includes a first semiconductor layer and a second semiconductor layer. The method further includes forming a sacrificial gate structure over a portion of the fin structure, removing an edge portion of the second semiconductor layer to form a cavity, and forming a dielectric spacer in the cavity. The forming of the dielectric spacer includes depositing a first spacer layer, and a first portion of the first spacer layer is deposited in the cavity and a second portion of the first spacer layer is deposited around the sacrificial gate structure. The forming of the dielectric spacer further includes performing a first etch process to form an opening in the first portion of the first spacer layer, performing a second etch process to remove the second portion of the first spacer layer, and depositing a second spacer layer in the opening.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device structure, comprising:
a substrate portion extending from a substrate;
a semiconductor layer disposed over the substrate portion;
a gate structure surrounding at least a portion of the semiconductor layer; and
first and second dielectric spacers disposed on the semiconductor layer, wherein a portion of the gate structure is disposed between the first and second dielectric spacers, and each of the first and second dielectric spacer comprises:
a first spacer layer; and
a second spacer layer disposed adjacent the first spacer layer, wherein the second spacer layer has an outer edge and an inner edge, and a length of the outer edge is substantially greater than a length of the inner edge.

2. The semiconductor device structure of claim 1, wherein the second spacer layer has a triangular cross section.

3. The semiconductor device structure of claim 1, wherein the second spacer layer has a trapezoidal cross section.

4. The semiconductor device structure of claim 1, wherein an opening is formed between the first and second spacer layers.

5. The semiconductor device structure of claim 1, wherein the first and second spacer layers comprise different materials.

6. The semiconductor device structure of claim 5, wherein the first spacer layer comprises a silicon based dielectric material.

7. The semiconductor device structure of claim 5, wherein the second spacer layer comprises a boron based dielectric material.

8. A method, comprising:
forming a fin structure from a substrate, wherein the fin structure includes a first semiconductor layer and a second semiconductor layer;
removing an edge portion of the second semiconductor layer to form a cavity; and
forming a dielectric spacer in the cavity, wherein the forming of the dielectric spacer comprises:
depositing a first spacer layer, wherein a first portion of the first spacer layer is deposited in the cavity;
performing a first etch process to form an opening in the first portion of the first spacer layer, wherein the opening has a dimension that decreases in a direction towards the second semiconductor layer; and
depositing a second spacer layer, wherein a first portion of the second spacer layer is deposited in the opening.

9. The method of claim 8, wherein the first etch process reduces a thickness of a second portion of the first spacer layer.

10. The method of claim 8, wherein the first etch process removes a second portion of the first spacer layer.

11. The method of claim 10, wherein the first etch process comprises a first time period and a second time period, wherein the first time period of the first etch process is anisotropic, and the second time period of the first etch process is isotropic.

12. The method of claim 11, wherein the first time period is substantially longer than the second time period.

13. The method of claim 11, wherein the first time period is before the second time period.

14. The method of claim 11, wherein the second time period is before the first time period.

15. The method of claim 8, further comprising performing a second etch process to remove a second portion of the second spacer layer.

16. A method, comprising:
forming a fin structure from a substrate, wherein the fin structure includes a first semiconductor layer and a second semiconductor layer;
forming a sacrificial gate structure over a portion of the fin structure;
removing an edge portion of the second semiconductor layer to form a cavity; and
forming a dielectric spacer in the cavity, wherein the forming of the dielectric spacer comprises:
depositing a first spacer layer, wherein a first portion of the first spacer layer is deposited in the cavity and a second portion of the first spacer layer is deposited around the sacrificial gate structure;
performing a first etch process to form an opening in the first portion of the first spacer layer;
performing a second etch process to remove the second portion of the first spacer layer; and
depositing a second spacer layer in the opening.

17. The method of claim 16, wherein the first etch process is an anisotropic etch process.

18. The method of claim 17, wherein the second etch process is an isotropic etch process.

19. The method of claim 18, wherein the first etch process is performed before the second etch process.

20. The method of claim 18, wherein the first etch process is performed after the second etch process.
